(19) United States
(12) Patent Application Publication
(10) Pub. No.: US 2025/0324594 A1
(43) Pub. Date: Oct. 16, 2025

(54) SEMICONDUCTOR STRUCTURES, MEMORY SYSTEMS AND METHODS OF FABRICATION OF SEMICONDUCTOR STRUCTURES

(71) Applicant: YANGTZE MEMORY TECHNOLOGIES CO., LTD., Wuhan (CN)

(72) Inventors: Dingding Shen, Wuhan (CN); Linchun Wu, Wuhan (CN); Kun Zhang, Wuhan (CN); Zehui Zhang, Wuhan (CN); Wenxi Zhou, Wuhan (CN); Zhiliang Xia, Wuhan (CN)

(21) Appl. No.: 18/754,091

(22) Filed: Jun. 25, 2024

(30) Foreign Application Priority Data
Apr. 12, 2024 (CN) 202410446820.7

(51) Int. Cl. H10B 43/27

(52) U.S. Cl. CPC H10B 43/27

(57) ABSTRACT

According to one aspect of the present disclosure, a semiconductor structure is provided. The semiconductor structure may include a stack structure. The semiconductor structure may include a gate line isolation structure penetrating through the stack structure and including a first isolation part and a second isolation part arranged in a first direction and both extending in the first direction. The semiconductor structure may include an insulating structure penetrating through the stack structure and connected between the first isolation part and the second isolation part. The first direction may intersect a stacking direction of the stack structure.

### CROSS-REFERENCE TO RELATED APPLICATIONS

The present application claims the benefit of priority to Chinese Application No. 202410446820.7, filed on Apr. 12, 2024, which is hereby incorporated by reference in its entirety.

### TECHNICAL FIELD

The present application relates to the field of semiconductor technology, and more particularly to a semiconductor structure, a memory system and a method of fabrication of the semiconductor structure.

### BACKGROUND

In order to increase the integration level of a semiconductor structure, the number of stacked layers in the semiconductor structure is increasing. However, a large number of stacked layers might increase the risk of falling of the semiconductor structure, thereby degrading the stability of the semiconductor structure, causing difficulty to achieve desired yield.

### SUMMARY

According to one aspect of the present disclosure, a semiconductor structure is provided. The semiconductor structure may include a stack structure. The semiconductor structure may include a gate line isolation structure penetrating through the stack structure and including a first isolation part and a second isolation part arranged in a first direction and both extending in the first direction. The semiconductor structure may include an insulating structure penetrating through the stack structure and connected between the first isolation part and the second isolation part. The first direction may intersect a stacking direction of the stack structure.

In some implementations, in a second direction, a size of the insulating structure may be greater than a size of the first isolation part and greater than a size of the second isolation part, and the first direction, the second direction and the stacking direction intersect each other.

In some implementations, the semiconductor structure may further include a filling structure penetrating through the insulating structure and having separating distances from the first isolation part and the second isolation part respectively in the first direction.

In some implementations, materials for the filling structure may include, from outside to inside, one of: silicon oxide and poly-crystalline silicon; silicon oxide, silicon nitride and poly-crystalline silicon; silicon oxide; or silicon oxide, poly-crystalline silicon and silicon oxide.

In some implementations, materials for the first isolation part, the second isolation part and the filling structure may be the same.

In some implementations, a material for the insulating structure may include silicon oxide.

In some implementations, in a plane perpendicular to the stacking direction, the stack structure may be divided into a storage region and a connection region in the first direction, and a plurality of the insulating structures may be arranged at intervals in the first direction in the storage region.

In some implementations, in the first direction, a size between adjacent insulating structures may be greater than or equal to 5 μm, and a size of the insulating structure is greater than or equal to 500 nm.

In some implementations, the semiconductor structure may further include a plurality of dielectric layers discontinuously covering end surfaces of the first isolation part and the second isolation part in the stacking direction. In some implementations, in a second direction, a size of the dielectric layer may be greater than a size of the first isolation part and greater than a size of the second isolation part, and the first direction, the second direction and the stacking direction may intersect each other.

In some implementations, in the first direction, a size between adjacent dielectric layers may be greater than or equal to 300 nm, and a size of the dielectric layer may be greater than or equal to 150 nm.

In some implementations, a material for the plurality of dielectric layers may include silicon oxide.

In some implementations, the stack structure may be divided into memory blocks by the gate line isolation structures and the insulating structures adjacent in the second direction, and the dielectric layers may connect adjacent memory blocks.

In some implementations, sidewalls of the first isolation part and the second isolation part may all in plane shapes.

In some implementations, the semiconductor structure may further include a channel structure extending in the stacking direction in the insulating structures.

According to another aspect of the present disclosure, a memory system is provided. The memory system may include a memory including a semiconductor structure. The semiconductor structure may include a stack structure. The semiconductor structure may include a gate line isolation structure penetrating through the stack structure and comprising a first isolation part and a second isolation part arranged in a first direction and both extending in the first direction. The semiconductor structure may include an insulating structure penetrating through the stack structure and connected between the first isolation part and the second isolation part. The first direction may intersect a stacking direction of the stack structure. The memory system may include a controller coupled with the memory and configured to control the memory to store data.

According to a further aspect of the present disclosure, a method of fabricating a semiconductor structure is provided. The method may include forming a first slit part, a first trench, and a second slit part penetrating through an initial stack structure. The initial stack structure may include first dielectric layers and second dielectric layers stacked alternatively. The first slit part, the first trench, and the second slit part may be arranged at intervals in a first direction. The first slit part and the second slit part may both extend in the first direction. The method may include replacing parts of the respective second dielectric layers at a periphery of the first trench with a plurality of third dielectric layers. The method may include forming a first isolation part and a second isolation part in the first slit part and the second slit part respectively. The first direction may intersect a stacking direction of the initial stack structure.

In some implementations, before replacing parts of the respective second dielectric layers at the periphery of the first trench with the plurality of third dielectric layers, the method may further include forming a sacrificial material layer in the first slit part and the second slit part. In some implementations, the replacing parts of the respective second dielectric layers at the periphery of the first trench with the plurality of third dielectric layers may include removing parts of the respective second dielectric layers at the periphery of the first trench to the sacrificial material layer and forming a plurality of first gaps. In some implementations, the replacing parts of the respective second dielectric layers at the periphery of the first trench with the plurality of third dielectric layers may include forming the plurality of third dielectric layers in the plurality of first gaps.

In some implementations, after replacing parts of the respective second dielectric layers at the periphery of the first trench with the plurality of third dielectric layers, the method may further include forming an initial fourth dielectric layer on sides of the initial stack structure and the sacrificial material layer in the stacking direction. In some implementations, after replacing parts of the respective second dielectric layers at the periphery of the first trench with the plurality of third dielectric layers, the method may further include removing a part of the initial fourth dielectric layer such that a plurality of fourth dielectric layers left are discontinuously located on a side of the sacrificial material layer, and the respective fourth dielectric layers left have sizes in the second direction being greater than a size of the sacrificial material layer in the second direction. In some implementations, the first direction, the second direction, and the stacking direction may intersect each other.

In some implementations, before forming the first isolation part and the second isolation part in the first slit part and the second slit part respectively, the method may further include removing the sacrificial material layer and exposing the first slit part and the second slit part. In some implementations, before forming the first isolation part and the second isolation part in the first slit part and the second slit part respectively, the method may further include removing at least parts of the respective second dielectric layers with the first slit part and the second slit part to form a plurality of second gaps. In some implementations, before forming the first isolation part and the second isolation part in the first slit part and the second slit part respectively, the method may further include forming a plurality of gate layers in the plurality of second gaps.

In some implementations, in a plane perpendicular to the stacking direction, the initial stack structure may be divided into a storage region and a connection region in the first direction, the first slit part is located in the storage region, and the second slit part may be located in the storage region and the connection region. In some implementations, removing at least parts of the respective second dielectric layers with the first slit part and the second slit part to form the plurality of second gaps may include removing parts of the respective second dielectric layers in the connection region with the second slit part. In some implementations, removing at least parts of the respective second dielectric layers with the first slit part and the second slit part to form the plurality of second gaps may include removing the respective second dielectric layers in the storage region with the first slit part and the second slit part to form the plurality of second gaps.

In some implementations, after replacing parts of the respective second dielectric layers at the periphery of the first trench with the plurality of third dielectric layers, the method may further include forming a filling structure in the first trench.

In some implementations, the filling structure, the first isolation part, and the second isolation part may be formed in a same thin film deposition process.

### BRIEF DESCRIPTION OF DRAWINGS

Through reading of the detailed description to non-limiting examples made with reference to the following figures, other characteristics, purposes and advantages of the present application will become more apparent.

FIG. 1 is a solid diagram of a semiconductor structure in an example of the present application;

FIGS. 2A to 2C are structure diagrams of a semiconductor structure in another example of the present application;

FIG. 3 is a flowchart of a method of fabrication of a semiconductor structure in an example of the present application;

FIGS. 4A to 18 are structure diagrams of a semiconductor structure in the fabrication process in an example of the present application;

FIG. 19 is a block diagram of a system having a memory system in an example of the present application; and

FIGS. 20A and 20B are diagrams of a memory system in an example of the present application.

### DETAILED DESCRIPTION

For better understanding of the application, various aspects of the application will be described in more detail with reference to accompanying drawings. It is to be appreciated that the detailed description is only for the purpose of explaining example implementations of the application and will in no way limit the scope of the application. Throughout the specification, identical reference numerals refer to identical elements. The expression “and/or” covers any and all combinations of one or more of the listed items.

It is to be noted that, throughout this specification, expressions such as “first”, “second”, “third” and the like are only used to distinguish one feature from another, and do not indicate any limitation to features, especially not indicating any order. Therefore, a first dielectric layer as discussed in the present application may also be referred to as a second dielectric layer and vice versa, without departing from the teachings of the present application.

In the figures, thicknesses, dimensions and shapes of components have been adjusted slightly for easy illustration. The figures are only examples and not strictly drawn to scale. As used herein, terms “approximate”, “about” and the like indicate approximation instead of degrees and are intended to illustrate inherent variations in measurement values or calculated values, which would be appreciated by those of ordinary skills in the art.

It is also to be appreciated that, as used herein, expressions such as “include”, “comprise”, “have” and/or “contain” are open rather than exclusive, i.e. they indicate existence of the stated feature, element and/or component, but will not exclude existence of one or more other features, elements, components and/or any combinations thereof. Furthermore, when the expression such as “at least one of” precedes a list of features, it defines all the listed features instead of any individual ones in the list. Furthermore, as used in the description of an implementation of the present application, the term “may” indicates “one or more implementations of the present application”. Also, the term “illustrative” refers to example or illustration.

All the terms (including engineering terms and scientific and technical terms) used herein have the same meanings as those commonly understood by those of ordinary skills in the art, unless otherwise specified. It is also to be appreciated that the terms defined in common dictionaries should be interpreted to have the meanings consistent with their contexts in pertinent arts and should not be interpreted in an idealized or overly formalized sense, unless otherwise specified explicitly in the application.

It is to be noted that implementations of the application and features thereof may be combined where there are no conflicts. Furthermore, specific operations contained in a method recited in the application may not necessarily be performed in the described order and instead may be performed in any other order or in parallel, unless there is an explicit definition or any conflict with the context.

Moreover, as used in the application, the term “connect” or “couple” may indicate direct or indirect contact between corresponding components, unless it is otherwise defined clearly or can be derived from the context.

The application will be described in detail hereafter in connection with examples with reference to accompanying drawings.

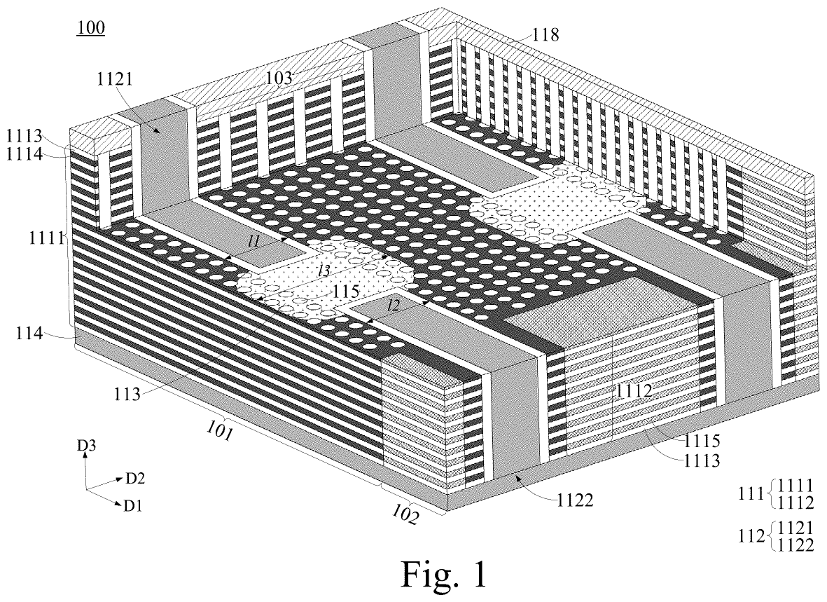

Some examples of the present application provide a semiconductor structure. FIG. 1 is a solid diagram of a semiconductor structure in an example of the present application. In order to show the internal structure of the semiconductor structure 100 more clearly, parts of the semiconductor structure 100 are removed in FIG. 1 to expose the internal structure of the semiconductor structure 100.

It shall be noted that D1 direction, D2 direction and D3 direction in drawings illustrate the spatial relationship of components in the semiconductor structure. For example, the D3 direction is a stacking direction of a stack structure (or initial stack structure), the D1 and the D2 direction are two directions intersecting (e.g., perpendicular to) each other on the plane intersecting (e.g., perpendicular to) the stacking direction respectively. For example, the D1 direction is an extension direction of a first isolation part or a second isolation part. Throughout the application, same concepts will be used to describe the spatial relationship among components in the semiconductor structure.

As shown in FIG. 1, the semiconductor structure 100 includes a stack structure 111, a gate line isolation structure 112 and an insulating structure 113. The gate line isolation structure 112 penetrates through the stack structure 111 and includes a first isolation part 1121 and a second isolation part 1122 arranged in the D1 direction. Both the first isolation part 1121 and the second isolation part 1122 extend in the D1 direction. The insulating structure 113 penetrates through the stack structure 111 and is connected between the first isolation part 1121 and the second isolation part 1122.

According to the semiconductor structure 100 provided in the above-described example, both the first isolation part 1121 and the second isolation part 1122 arranged in the D1 direction extend in the D1 direction and penetrate through the stack structure 111. The fact that the insulating structure 113 penetrates through the stack structure 111 and is connected between the first isolation part 1121 and the second isolation part 1122 facilitates optimizing the structure stress, limiting the falling problem of the semiconductor structure and improving the stability and yield of the semiconductor structure 100. At the same time, the insulating structure 113 and the gate line isolation structure 112 can also electrically isolate the stack structure 111 on both sides thereof.

In some implementations, the stack structure 111 may include a first stack part 1111 and a second stack part 1112. As viewed in the D3 direction, the first stack part 1111 surrounds at least partially the second stack part 1112. The first stack part 1111 may include first dielectric layers 1113 and gate layers 1114 stacked alternatively in the D3 direction. The second stack part 1112 may include the first dielectric layers 1113 and second dielectric layers 1115 stacked alternatively in the D3 direction. For example, the respective first dielectric layers 1113 in the first stack part 1111 and the second stack part 1112 continually extend laterally in a plane perpendicular to the D3 direction and may be an integral structure. The respective gate layers 1114 and second dielectric layers 1115 are connected in one-to-one correspondence and extend laterally in the plane perpendicular to the D3 direction respectively.

In some implementations, the material for the first dielectric layer 1113 may include one or more of silicon oxide (SiO₂), silicon nitride (Si₃N₄), silicon oxynitride (SiOₓN_{y}) or any other suitable insulative materials. For example, the material for the first dielectric layer 1113 may be silicon oxide (SiO₂). The material for the gate layer 1114 may include one or more of titanium (Ti), titanium nitride (TiN), tantalum (Ta), tantalum nitride (TaN), poly-crystalline silicon (poly-Si), amorphous silicon (a-Si), tungsten (W), molybdenum (Mo), copper (Cu), aluminum (Al), ruthenium (Ru) or any other suitable conductive materials. The material for the second dielectric layer 1115 may include one or more of silicon oxide (SiO₂), silicon nitride (Si₃N₄), silicon oxynitride (SiOₓN_{y}) or any other suitable insulative materials. The material for the second dielectric layer 1115 may be different from that of the first dielectric layer 1113. For example, the material for the second dielectric layer 1115 may be silicon nitride (Si₃N₄).

In some implementations, in the plane perpendicular to the D3 direction, the stack structure 111 may be divided into a storage region 101 and a connection region 102 in the D1 direction. For example, the first stack part 1111 is located in the storage region 101 and partly in the connection region 102 while the second stack part 1112 is located in the connection region 102. The first stack part 1111 in the connection region 102 may be located on both sides of the second stack part 1112 in the D2 direction.

In some other implementations, the stack structure may include the first dielectric layers and the gate layers stacked alternatively in the D3 direction and the stack structure in the connection region has a step structure (not shown).

In some implementations, the gate line isolation structure 112 extends in the storage region 101 and the connection region 102 and is separated into a first isolation part 1121 and a second isolation part 1122 by the insulating structure 113. For example, the first stack part 1111 in the connection region 102 may contact the second isolation part 1122.

In some implementations, the material for a part of the gate line isolation structure 112 that contacts the first stack part 1111 includes one or more of silicon oxide (SiO₂), silicon nitride (Si₃N₄), silicon oxynitride (SiOₓN_{y}) or any other suitable insulative materials.

In some implementations, the constituting materials for the first isolation part 1121 and the second isolation part 1122 in the gate line isolation structure 112 may be the same. For example, the materials for the first isolation part 1121 and the second isolation part 1122 may include silicon oxide (SiO₂) and poly-crystalline silicon (poly-Si) from outside to inside. The gate line isolation structure 112 having the above-described material combination facilitates improving stress distribution. As another example, the first isolation part 1121 and the second isolation part 1122 may be made of a single material, which is not limited specifically in the present application.

In some implementations, the stack structure 111 is divided into memory blocks 103 by the gate line isolation structures 112 and the insulating structures 113 being adjacent in the D1 direction.

In some implementations, the sidewalls of the first isolation part 1121 and the second isolation part 1122 are all in plane shapes.

In some implementations, in the D2 direction, a size l3 of the insulating structure 113 is greater than a size l1 of the first isolation part 1121, and the size l3 of the insulating structure 113 is greater than a size l2 of the second isolation part 1122. The insulating structure 113 extending into the stack structure 111 in the D2 direction further improves the stability and yield of the semiconductor structure 100.

In some implementations, the material for the insulating structure 113 may include one or more of silicon oxide (SiO₂), silicon nitride (Si₃N₄), silicon oxynitride (SiOₓN_{y}) or any other suitable insulative materials. For example, the insulating structure 113 is made of a single material such as silicon oxide (SiO₂).

In some implementations, the semiconductor structure 100 may further include a semiconductor layer 114. The semiconductor layer 114 may be located on a side of the stack structure 111 in the D3 direction and extend laterally in the D1 direction and the D2 direction. The material for the semiconductor layer 114 may include at least one of single crystalline silicon, poly-crystalline silicon, single-crystalline germanium, III-V compound semiconductor materials, II-VI compound semiconductor materials or other semiconductor materials known in the prior art. For example, the material for the semiconductor layer 114 may be silicon (Si).

In some implementations, the semiconductor structure 100 may further include a channel structure 115. The channel structure 115 may be approximately in a pillar structure and extend in the D3 direction. In the plane perpendicular to the D3 direction, a plurality of channel structures 115 are arranged in an array in the D1 direction and the D2 direction. For example, in the storage region 101, some channel structures 115 penetrate through the first stack part 1111 while some channel structures 115 penetrate through the insulating structure 113. For example, the channel structures 115 may extend into the semiconductor layer 114 in the D3 direction.

In some implementations, the semiconductor structure 100 may further include an insulating layer 118. The insulating layer 118 may be located on a side of the stack structure 111 away from the semiconductor layer 114 in the D3 direction and extend laterally in the D1 direction and the D2 direction. For example, the insulating layer 118 may cover surfaces of the channel structures 115 and the stack structure 111. As another example, the first isolation part 1121 and the second isolation part 1122 may penetrate through the insulating layer 118. The material for the insulating layer 118 may include one or more of silicon oxide (SiO₂), silicon nitride (Si₃N₄), silicon oxynitride (SiOₓN_{y}) or any other suitable insulative materials. It is to be noted that in case that the insulating layer 118 contacts the first dielectric layers 1113 in the stack structure 111 and both have the same material, there are no evident interfaces therebetween.

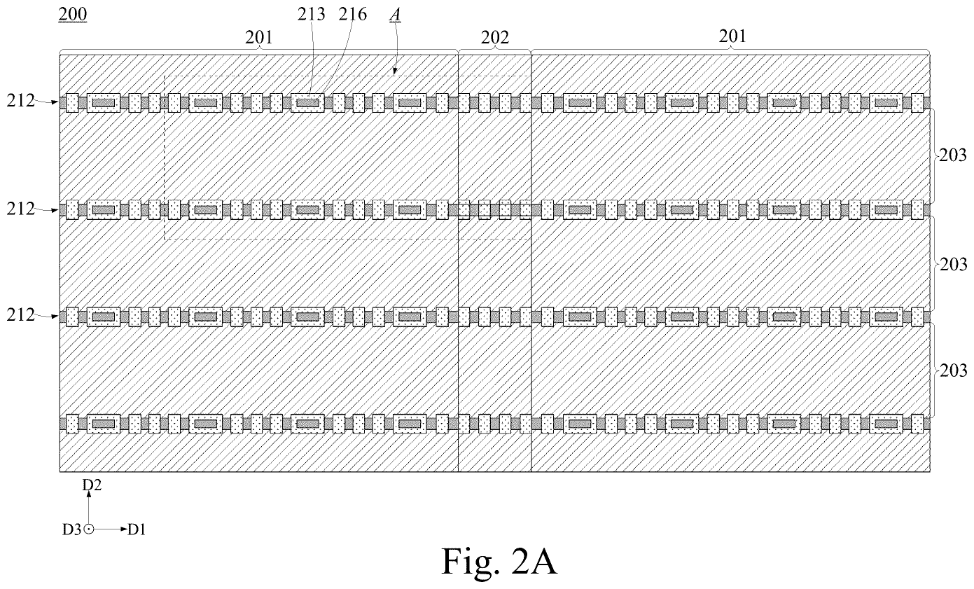

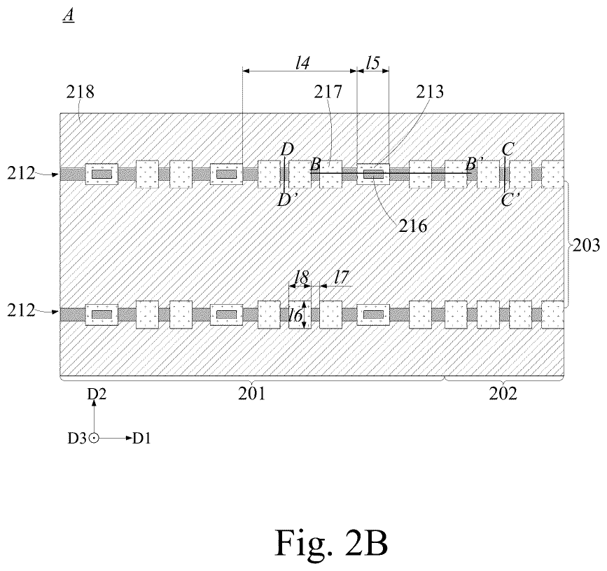

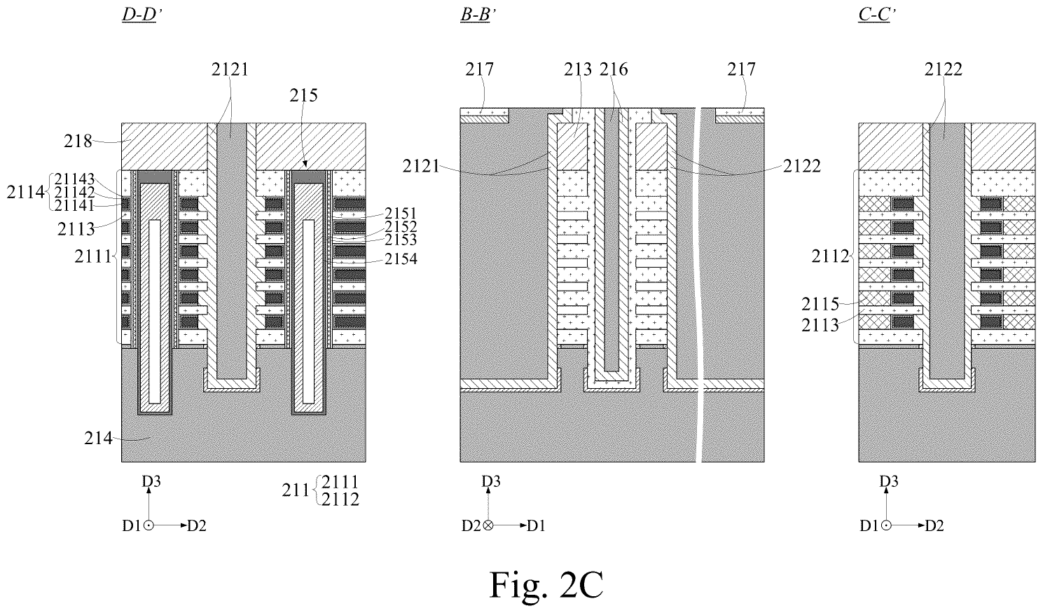

FIGS. 2A to 2C are structure diagrams of a semiconductor structure in another example of the present application. Among them, FIG. 2A is a top view of the semiconductor structure 200. FIG. 2B is a partially enlarged view of region A shown in FIG. 2A. FIG. 2C is sectional views taken along line B-B′, line C-C′ and line D-D′ shown in FIG. 2B. For concise description, the same contents as those in the previous example will not be described any more.

As shown in FIGS. 2A to 2C, the semiconductor structure 200 includes a stack structure 211, a gate line isolation structure 212 and an insulating structure 213. The gate line isolation structure 212 penetrates through the stack structure 211 and includes a first isolation part 2121 and a second isolation part 2122 arranged in a D1 direction. Both the first isolation part 2121 and the second isolation part 2122 extend in the D1 direction. The insulating structure 213 penetrates through the stack structure 211 and is connected between the first isolation part 2121 and the second isolation part 2122.

In some implementations, the stack structure 211 may include a first stack part 2111 and a second stack part 2112. As viewed in the D3 direction, the first stack part 2111 surrounds at least partially the second stack part 2112. The first stack part 2111 may include first dielectric layers 2113 and gate layers 2114 stacked alternatively in the D3 direction. The second stack part 2112 may include the first dielectric layers 2113 and second dielectric layers 2115 stacked alternatively in the D3 direction.

In some implementations, the gate layer 2114 may include a metal layer 21141, an adhesion layer 21142 and a gate blocking layer 21143. The adhesion layer 21142 surrounds the metal layer 21141, and the gate blocking layer 21143 surrounds the adhesion layer 21142. The material for the metal layer 21141 may include one or more of tungsten (W), molybdenum (Mo), copper (Cu), aluminum (Al), ruthenium (Ru) or any other suitable metal materials. The material for the adhesion layer 21142 may include one or more of titanium (Ti), titanium nitride (TiN), tantalum (Ta), tantalum nitride (TaN) or any other suitable materials. The material for the gate blocking layer 21143 may include one or more of aluminum oxide (Al₂O₃), titanium oxide (TiO₂), tantalum oxide (Ta₂O₃), hafnium oxide (HfO₂) or any other suitable high dielectric constant materials.

In some implementations, the semiconductor structure 200 may further include a filling structure 216. The filling structure 216 penetrates through the insulating structure 213 and has separating distances from the first isolation part 2121 and the second isolation part 2122 in the D1 direction respectively. For example, in a plane perpendicular to the D3 direction, the filling structure 216 is approximately located in the middle of the insulating structure 213. In other words, the insulating structure 213 may surround the periphery of the filling structure 216.

In some implementations, the material or material combination for the filling structure 216 may include, from outside to inside, one of: silicon oxide (SiO₂) and poly-crystalline silicon (poly-Si); silicon oxide (SiO₂), silicon nitride (Si₃N₄) and poly-crystalline silicon (poly-Si); silicon oxide (SiO₂), poly-crystalline silicon (poly-Si) and silicon oxide (SiO₂). For example, FIG. 2C shows that the materials for the filling structure 216 include silicon oxide (SiO₂) and poly-crystalline silicon (poly-Si) from outside to inside. It is to be noted that when the material for the insulating structure 213 and the material for the filling structure 216 are the same, for example, a single material such as silicon oxide (SiO₂), there is no evident interface between them. For example, they may be the insulating structure 113 shown in FIG. 1.

In some implementations, the constituting materials for the first isolation part 2121 and the second isolation part 2122 in the gate line isolation structure 212 and the filling structure 216 may be the same. For example, the materials for the first isolation part 2121, the second isolation part 2122 and the filling structure 216 may include silicon oxide (SiO₂) and poly-crystalline silicon (poly-Si) from outside to inside. The gate line isolation structure 212 having the above-described material combination facilitates improving stress distribution. Furthermore, the first isolation part 2121, the second isolation part 2122 and the filling structure 216 having the same constituting material may be formed in the same process, which improves fabrication efficiency and reduces manufacturing costs.

In some implementations, in the plane perpendicular to the D3 direction, the stack structure 211 may be divided into a storage region 201 and a connection region 202 in the D1 direction. For example, in the D1 direction, the connection region 202 is located between two storage regions 201. A plurality of insulating structures 213 may be arranged at intervals in the D1 direction in the storage region 201. Generally, in the plane perpendicular to the D3 direction, an area of the storage region 201 is greater than an area of the connection region 202. Disposing the plurality of insulating structures 213 in the storage region 201 facilitates improving the stability of stack structure 211 in the storage region 201, thereby improving stability and increasing the yield of the semiconductor structure 200. In some other implementations, the plurality of insulating structures may be arranged at intervals (not shown) in the D1 direction in the connection region, which is not specifically limited herein.

In some implementations, as shown in FIG. 2B, in the D1 direction, a size l4 between the adjacent insulating structures 213 is greater than or equal to 5 μm, and a size l5 of the insulating structure 213 is greater than or equal to 500 nm.

In some implementations, the semiconductor structure 200 may further include a plurality of dielectric layers 217 (hereinafter, the fourth dielectric layers 217). The plurality of fourth dielectric layers 217 may discontinuously cover the end surfaces of the first isolation part 2121 and the second isolation part 2122 in the D3 direction. In the D2 direction, a size l6 of the fourth dielectric layer 217 is greater than the size l1 of the first isolation part 2121 (referring to FIG. 1), and is greater than the size l2 of the second isolation part 2122 (referring to FIG. 1). For example, in the plane perpendicular to the D3 direction, the fourth dielectric layer 217 may be approximately in a rectangle shape. In this implementation, the fourth dielectric layers 217 crossing the gate line isolation structure 212 in the D2 direction may further improve the stability and yield of the semiconductor structure 200.

In some implementations, the material for the fourth dielectric layers 217 may include one or more of silicon oxide (SiO₂), silicon nitride (Si₃N₄), silicon oxynitride (SiOₓN_{y}) or any other suitable insulative materials. For example, the material for the fourth dielectric layers 217 may be silicon oxide (SiO₂). When the material for the insulating layer 218 and the material for the fourth dielectric layers 217 are both silicon oxide (SiO₂), there is no evident interface between them.

In some implementations, as shown in FIG. 2B, in the D1 direction, a size l7 between the adjacent fourth dielectric layers 217 may be greater than or equal to 300 nm, and a size l8 of the fourth dielectric layer 217 may be greater than or equal to 150 nm.

In some implementations, the stack structure 211 is divided into memory blocks 203 by the gate line isolation structures 212 and the insulating structures 213 being adjacent in the D1 direction. The fourth dielectric layers 217 connect the adjacent memory blocks 203. For example, the fourth dielectric layer 217 extending to the adjacent memory blocks 203 in the D2 direction can improve the stability of the adjacent memory blocks 203, thereby improving the stability and yield of the semiconductor structure 200.

In some implementations, as shown in FIG. 2C, in the semiconductor structure 200, the channel structure 215 may include a charge barrier layer 2151, a charge trapping layer 2152, a tunneling layer 2153 and a channel layer 2154 disposed in this order from outside to inside. Materials for the charge barrier layer 2151, the charge trapping layer 2152 and the tunneling layer 2153 may include silicon oxide (SiO₂), silicon nitride (Si₃N₄) and silicon oxide (SiO₂) in turn. The material for the channel layer 2154 may include amorphous silicon (a-Si), poly-crystalline silicon (poly-Si) or any other suitable semiconductor materials. The charge barrier layer 2151, charge trapping layer 2152 and tunneling layer 2153 may be referred to as storage function layers. For example, the channel layer 2154 may project from the first stack part 2111 and extend into the semiconductor layer 214, and the storage function layers may surround a part of the channel layer 2154 penetrating through the first stack part 2111. When the material for the channel layer 2154 and the semiconductor layer 214 are the same, there is no evident interface between them.

In some implementations, a part of the channel structure 215 that is surrounded by a gate layer 2114 and a part of the gate layer 2114 constitute a memory cell. A plurality of memory cells are arranged in series along the extension direction such as the D3 direction of the channel structure 215 to constitute a memory cell string and share the channel layer 2154.

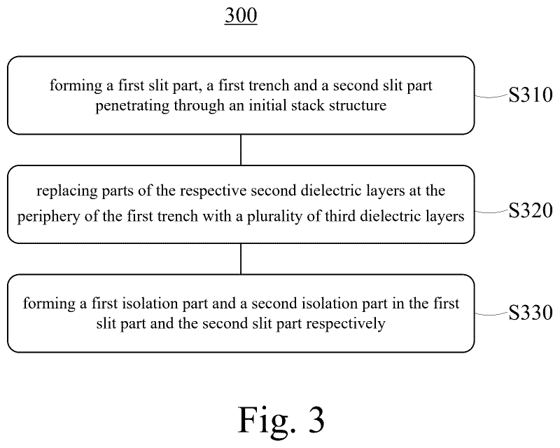

Some examples of the present application provide a method of fabrication of a semiconductor structure. FIG. 3 is a flowchart of a method of fabrication of a semiconductor structure in an example of the present application. As shown in FIG. 3, the method of fabricating 300 of the semiconductor structure (hereinafter, method of fabricating 300) may include the following operations.
Operation S310: forming a first slit part, a first trench and a second slit part penetrating through the initial stack structure, wherein the initial stack structure includes first dielectric layers and second dielectric layers stacked alternatively, the first slit part, the first trench and the second slit part are arranged at intervals in a first direction, and the first slit part and the second slit part both extend in the first direction.
Operation S320: replacing parts of the respective second dielectric layers at the periphery of the first trench with a plurality of third dielectric layers.
Operation S330: forming a first isolation part and a second isolation part in the first slit part and the second slit part respectively.

According to the method of fabrication provided in the example of the present application, by reasonably designing the positions and arrangement of the first slit part, the first trench and the second slit part, and replacing the parts of the respective second dielectric layers at periphery of the first trench with the plurality of third dielectric layers to form the insulating structure, the falling problem during the fabrication process may be limited or eliminated, while the stability and yield of the structure is improved.

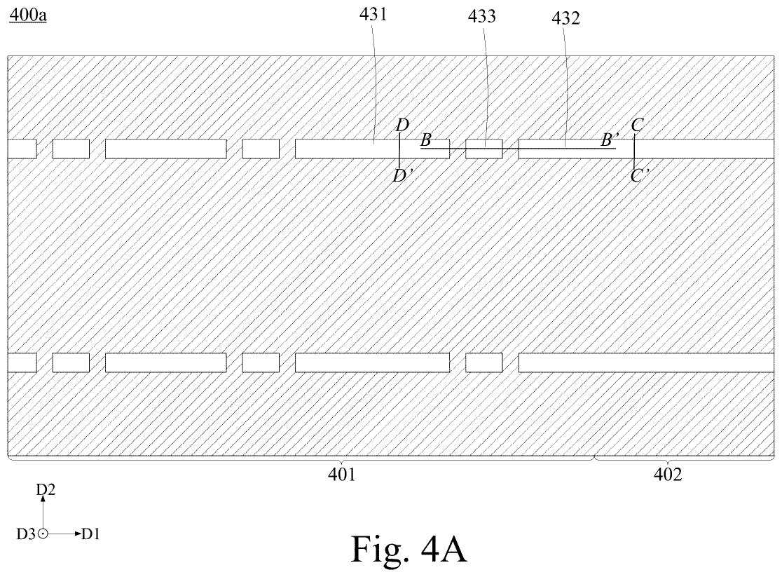

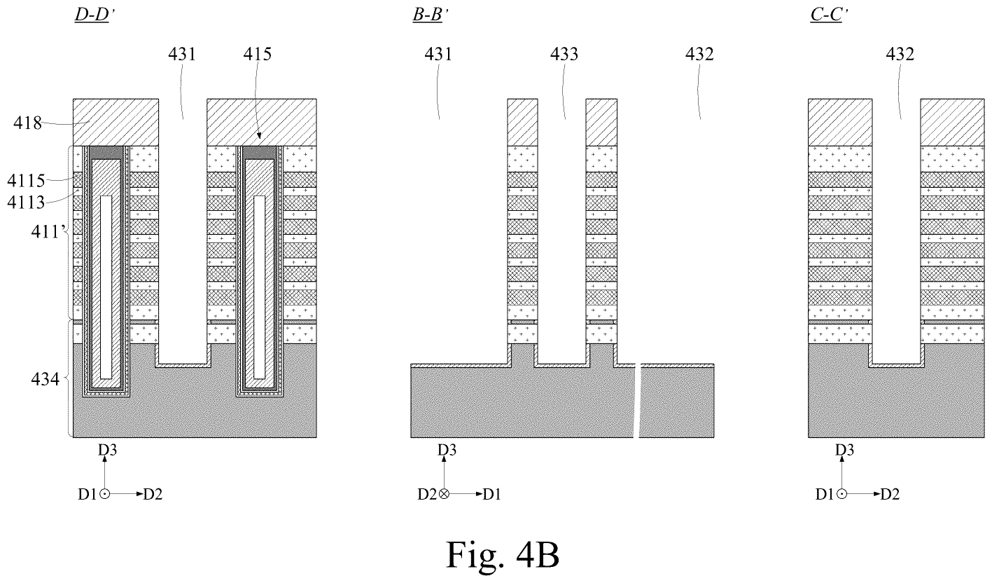

FIGS. 4A to 18 are structure diagrams of a semiconductor structure in the fabrication process in an example of the present application. For example, FIGS. 4A to 18 may serve to form the semiconductor structure 200 shown in FIGS. 2A to 2C. The method of fabrication 300 including operations S310 to S330 will be illustrated with reference to FIGS. 4A to 18.

### Example Implementation(s) of Operation S310

FIGS. 4A and 4B show an intermediate structure 400a after forming the first slit part 431, the second slit part 432 and the first trench 433. FIG. 4A is a top view of the intermediate structure 400a. FIG. 4B is sectional views taken along line B-B′, line C-C′ and line D-D′ shown in FIG. 4A.

As shown in FIGS. 4A and 4B, the first slit part 431, the second slit part 432 and the first trench 433 penetrating through the initial stack structure 411′ may be formed with etching process (such as dry etching and/or wet etching). The initial stack structure 411′ includes the first dielectric layers 4113 and the second dielectric layers 4115 stacked alternatively. The first slit part 431, the first trench 433 and the second slit part 432 are arranged at intervals in the D1 direction, and the first slit part 431 and the second slit part 432 both extend in the D1 direction.

In some implementations, in the D2 direction, the first slit part 431, the first trench 433 and the second slit part 432 may have approximately the same size. In the D1 direction, the size of the first slit part 431 may be greater than the size of the first trench 433, and the size of the second slit part 432 may be greater than the size of the first trench 433.

In some implementations, sidewalls of the first slit part 431 and the second slit part 432 are all in plane shapes.

In some implementations, the first dielectric layers 4113 and the second dielectric layers 4115 may be formed alternatively to form the initial stack structure 411′ with thin film deposition process such as chemical vapor deposition (CVD), physical vapor deposition (PVD), atomic layer deposition (ALD) or any combination thereof. For example, in the plane perpendicular to the D3 direction, the initial stack structure 411′ may be divided into a storage region 401 and a connection region 402 in the D1 direction. The respective first dielectric layers 4113 and the respective second dielectric layers 4115 may continually extend laterally in the storage region 401 and the connection region 402. For example, the material for the first dielectric layers 4113 may include silicon oxide (SiO₂), and the material for the second dielectric layers 4115 may include silicon nitride (Si₃N₄).

In some implementations, the initial stack structure 411′ may be formed on a surface of a substrate 434. For example, the substrate 434 may include a semiconductor substrate. The material for the semiconductor substrate may include silicon (Si), germanium (Ge), gallium arsenide (GaAs) or indium phosphate (InP). As another example, the semiconductor substrate may include a silicon-on-insulator (SOI) substrate or a germanium-on-insulator (GeOI) substrate. In some examples, the substrate 434 may be composite layer structure. In some other examples, the substrate 434 may be composed of a single material. For example, the substrate 434 may serve to support during the fabrication process and be removed at least partially in subsequent process.

In some implementations, after forming the initial stack structure 411′ and before forming the first slit part 431, the second slit part 432 and the first trench 433, it is possible to form the channel structure 415 penetrating through the initial stack structure 411′ and extending into the substrate 434. For example, the number of the channel structures 415 may be plurality. In the plane perpendicular to the z direction, a plurality of channel structures 415 are arranged in an array in the D1 direction and the D2 direction in the storage region 401.

In some implementations, after forming the channel structures 415 and before forming the first slit part 431, the second slit part 432 and the first trench 433, it is possible to form an insulating layer 418 covering the initial stack structure 411′ and the channel structures 415 with thin film deposition process such as CVD, PVD, ALD or any combination thereof. For example, the insulating layer 418 may extend laterally in the storage region 401 and the connection region 402. In case that the method of fabrication 300 includes an operation of forming the insulating layer 418, the first slit part 431, the second slit part 432 and the first trench 433 may penetrate through the insulating layer 418.

### Example Implementation(s) of Operation S320

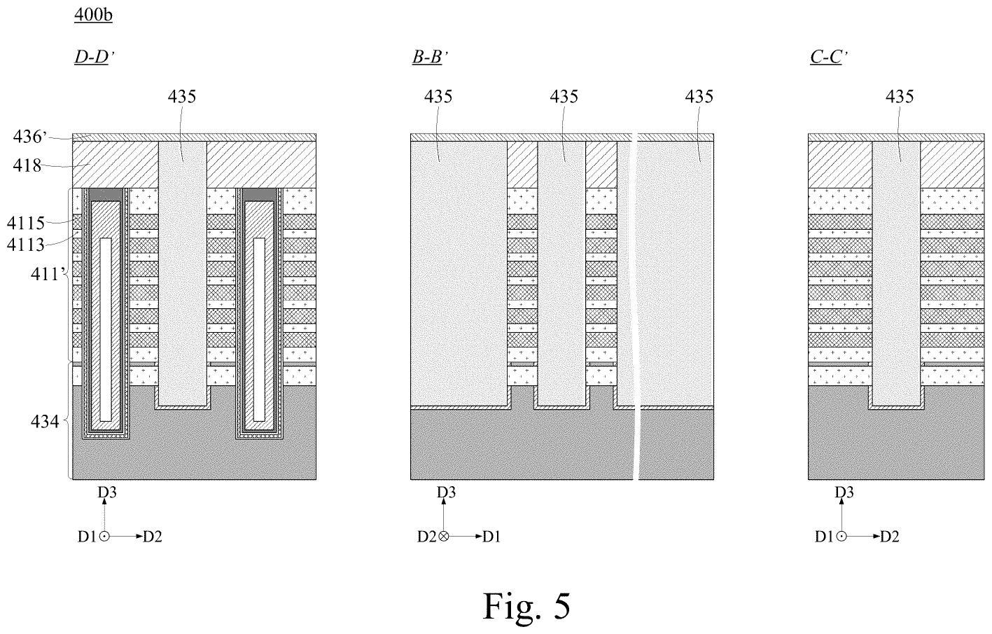

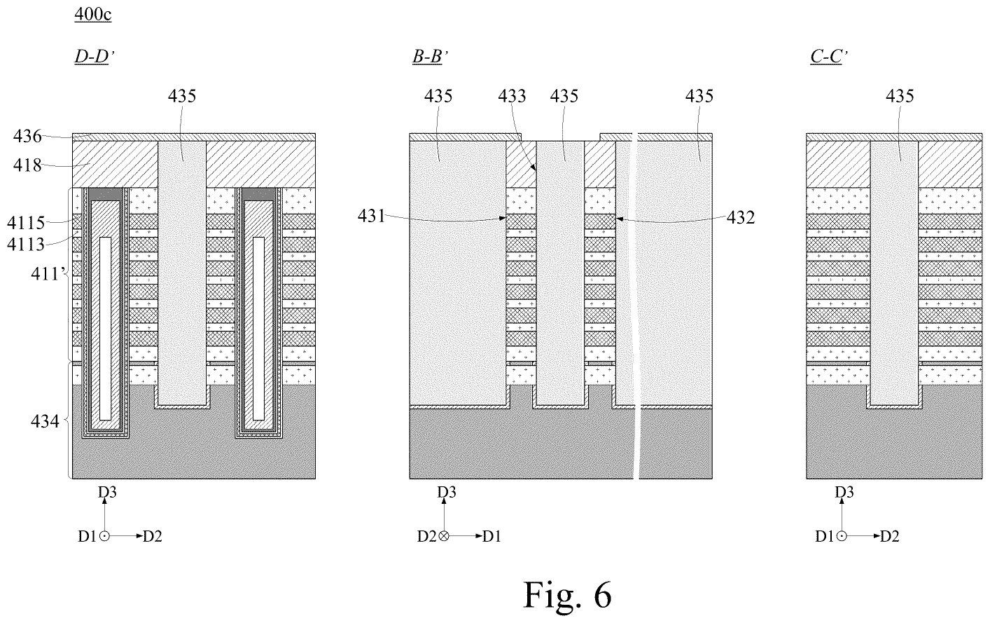

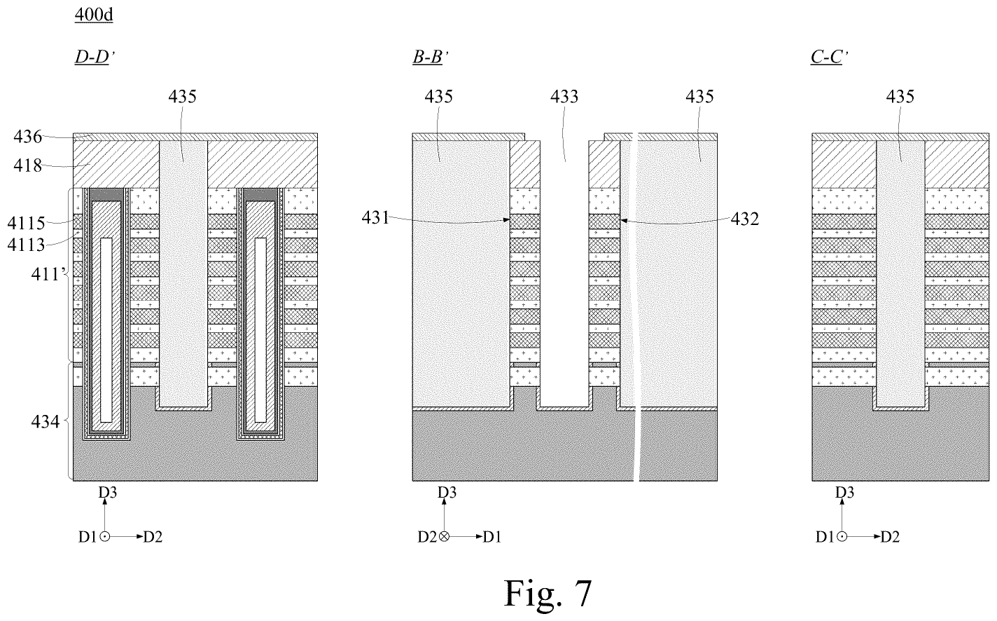

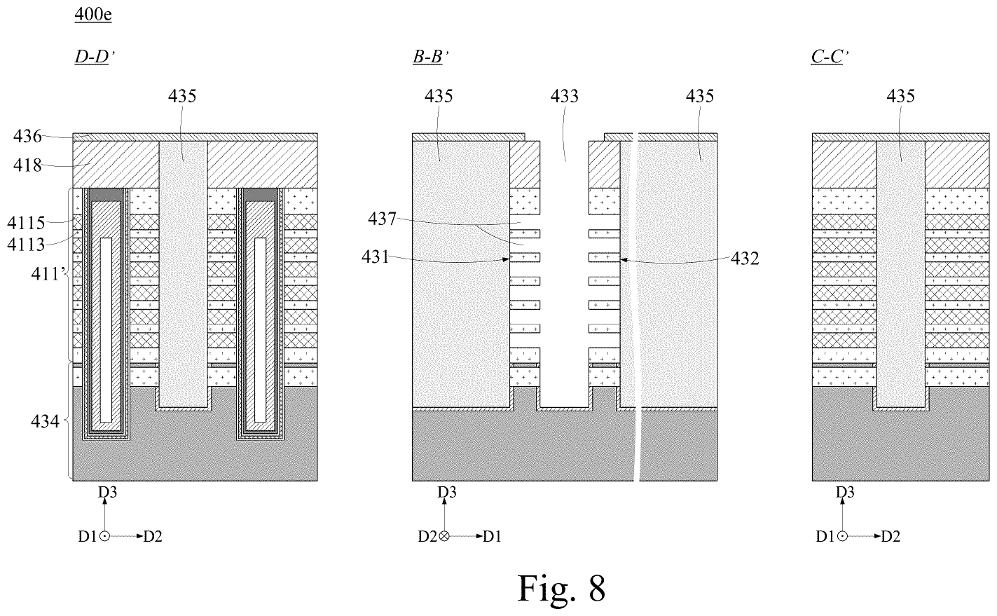

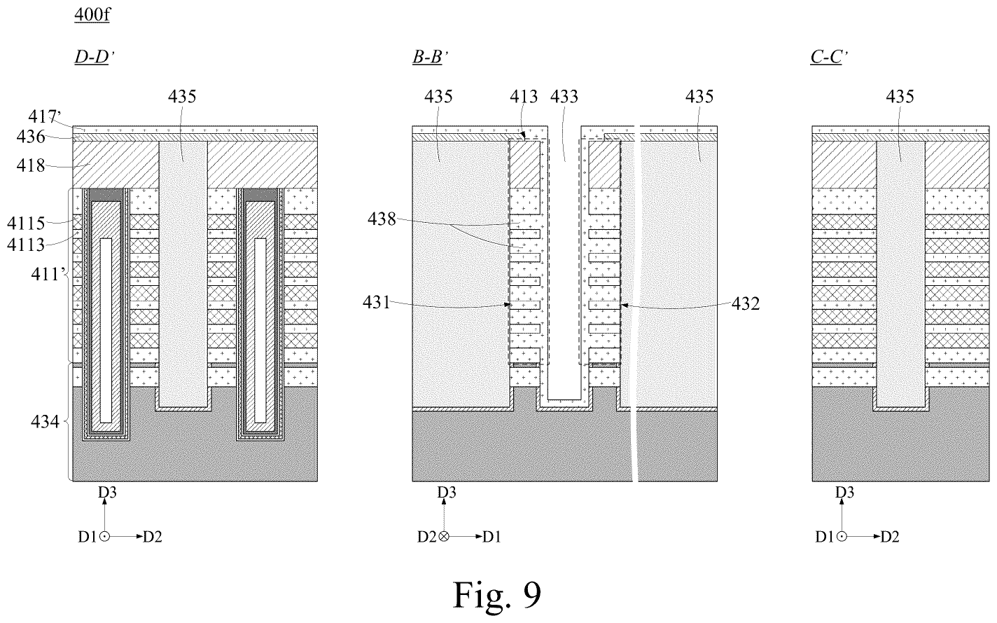

FIG. 5 shows an intermediate structure 400b after forming the first sacrificial material layer 435. FIG. 6 shows an intermediate structure 400c after forming the first mask layer 436. FIG. 7 shows an intermediate structure 400d after removing the first sacrificial material layer 435 in the first trench 433. FIG. 8 shows an intermediate structure 400e after forming a plurality of gaps 437. FIG. 9 shows an intermediate structure 400f after forming a plurality of third dielectric layers 438.

As shown in FIGS. 4A, 4B and 9, parts of the respective second dielectric layers 4115 at the periphery of the first trench 433 are replaced with a plurality of third dielectric layers 438. A plurality of third dielectric layers 438 and second dielectric layers 4115 between the adjacent third dielectric layers 438 constitute the insulating structure 413 (structure in dashed box). The insulating structure 413 may penetrate through the initial stack structure 411′.

In some implementations, the material for the third dielectric layers 438 may be different from that of the second dielectric layer 4115. For example, in case that the material for the second dielectric layers 4115 is silicon nitride (Si₃N₄), the material for the third dielectric layers 438 may include silicon oxide (SiO₂). For example, the first dielectric layer 4113 and the third dielectric layers 438 may be formed of the same material such as silicon oxide (SiO₂). It is to be noted that the interface between the first dielectric layer 4113 and the third dielectric layer 438 as shown in FIG. 9 serves to represent the spatial relationship between them, and in case that the material for the first dielectric layer 4113 and the material for the third dielectric layer 438 are the same, there is no evident interface between them. In some other implementations, the third dielectric layers 438 may be of one or more of any other suitable insulative materials, which is not limited herein.

The operation S320 will be illustrated below with reference to FIGS. 4A to 9.

In some implementations, as shown in FIGS. 4A, 4B and 5, after forming the first slit part 431, the second slit part 432 and the first trench 433, it is possible to form a first sacrificial material layer 435 in the first slit part 431, the second slit part 432 and the first trench 433 with thin film deposition process such as CVD, PVD, ALD or any combination thereof. The material for the first sacrificial material layer 435 may include poly-crystalline silicon (poly-Si), carbon (C) or any other suitable easy-to-remove materials. Subsequently, the initial first mask layer 436′ covering the insulating layer 418 may be formed with thin film deposition process such as CVD, PVD, ALD or any combination thereof. For example, the initial first mask layer 436′ may extend laterally in the D2 direction and the D3 direction. The material for the initial first mask layer 436′ may be different from that of the first sacrificial material layer 435. For example, the material for the initial first mask layer 436′ may include silicon oxide (SiO₂).

In some implementations, as shown in FIGS. 5 and 6, a part of the initial first mask layer 436′ may be removed with photolithography or etching process such as dry etching process to form an opening exposing the first sacrificial material layer 435 in the first trench 433 and transform the initial first mask layer 436′ into the first mask layer 436. The first mask layer 436 covers the insulating layer 418 and the first sacrificial material layer 435 in the first slit part 431 and the second slit part 432.

In some implementations, as shown in FIGS. 6 and 7, the first sacrificial material layer 435 in the first trench 433 may be removed with etching process such as wet etching process. The first mask layer 436 functions to mask and protect the first sacrificial material layer 435 in the first slit part 431 and the second slit part 432 from being removed. After the above-described processes, the first sacrificial material layer 435 may be only formed in the first slit part 431 and the second slit part 432. Optionally, after removing the first sacrificial material layer 435 in the first trench 433, the first mask layer 436 may be removed (not shown).

In some implementations, as shown in FIGS. 7 and 8, parts of the respective second dielectric layers 4115 at periphery of the first trench 433 may be removed to the first sacrificial material layer 435 with etching process such as wet etching process, and a plurality of first gaps 437 are formed. For example, in case that the material for the first dielectric layer 4113 and the material for the second dielectric layer 4115 are different, the etching material such as etchant isotropically removes parts of the respective second dielectric layers 4115 to the first sacrificial material layer 435 via the first trench 433 and leaves the respective first dielectric layers 4113 at periphery of the first trench 433. For example, as described above, the first slit part 431, the first trench 433 and the second slit part 432 are arranged at intervals in the D1 direction. In the process of isotropically removing parts of the respective second dielectric layers 4115, the first sacrificial material layer 435 in the first slit part 431 and the second slit part 432 may serve as the etch stop layer. Therefore, the plurality of first gaps 437 may expose the first sacrificial material layer 435 in the first slit part 431 and the second slit part 432, and the size of the respective first gap 437 in the D2 direction may be greater than the size of the first slit part 431 in the D2 direction, and greater than the size of the second slit part 432 in the D2 direction.

In some implementations, as shown in FIGS. 8 and 9, a plurality of third dielectric layers 438 may be formed in the plurality of first gaps 437, and the insulating structure 413 may be formed with thin film deposition process such as CVD, PVD, ALD or any combination thereof. The size of the insulating structure 413 in the D2 direction may be greater than the size of the first slit part 431 in the D2 direction, and greater than the size of the second slit part 432 in the D2 direction.

In some implementations, as shown in FIG. 9, in the process of forming the plurality of third dielectric layers 438, it is possible to form a film layer of the same material as the third dielectric layers 438 on inner walls of the first trench 433 and keep a part of the first trench 433 in un-filled state. In some other implementations, it is possible to completely fill the first trench 433 with the film layer of the same material as the third dielectric layers 438 such that the first trench 433 is in filled state.

In some implementations, in the process of forming the plurality of third dielectric layers 438, a film layer of the same material as the third dielectric layers 438 may be formed on a side of the initial stack structure 411′ and the first sacrificial material layer 435 in the D3 direction, such as on the surface of the first mask layer 436, which may be referred to as an initial fourth dielectric layer 417′.

In some implementations, the method of fabrication 300 may further include the following operations: removing a part of the initial fourth dielectric layer such that the left plurality of fourth dielectric layers are discontinuously located on a side of the sacrificial material layer, and the left fourth dielectric layers have sizes in the second direction being greater than the size of the sacrificial material layer in the second direction; removing the sacrificial material layer and exposing the first slit part and the second slit part; removing at least parts of the second dielectric layers with the first slit part and the second slit part to form a plurality of second gaps; and forming a plurality of gate layers in the plurality of second gaps.

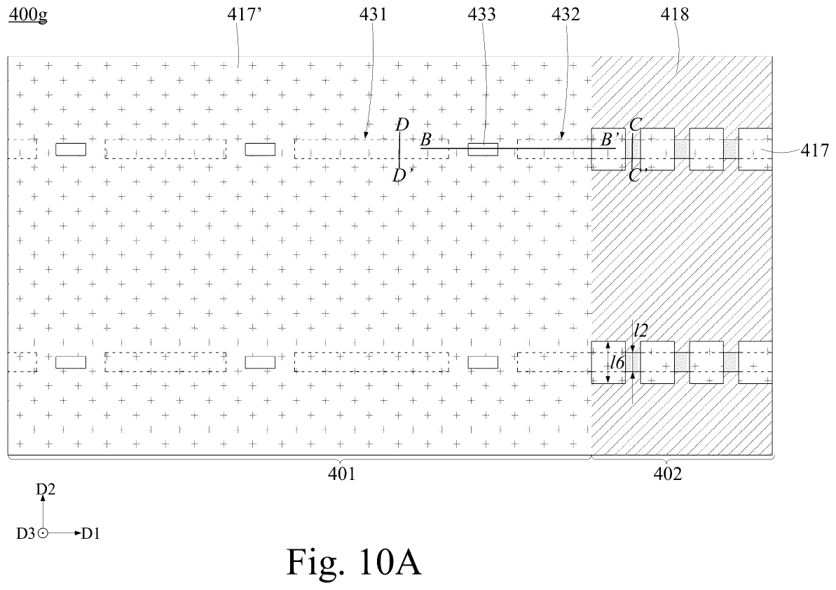

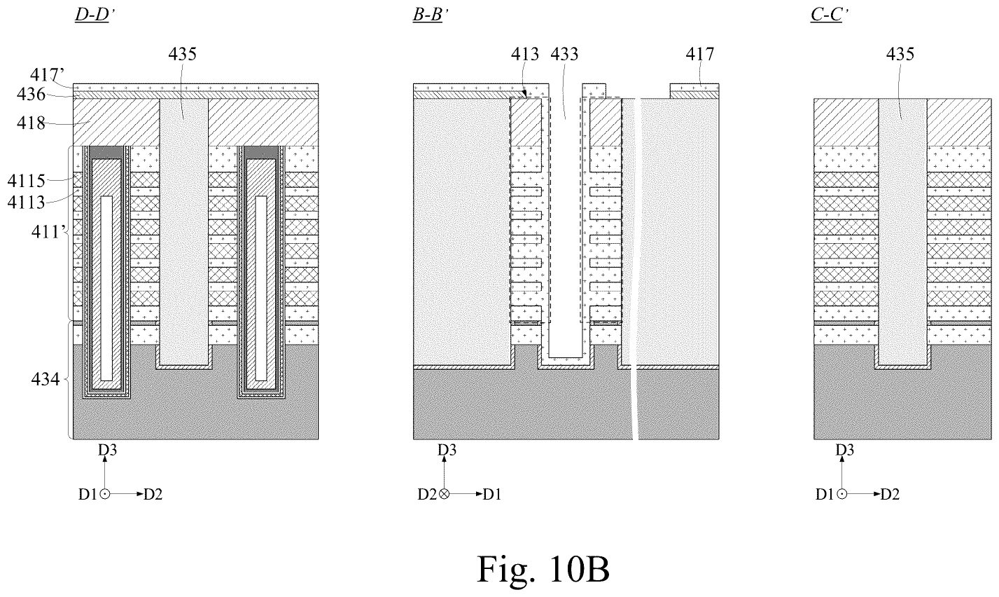

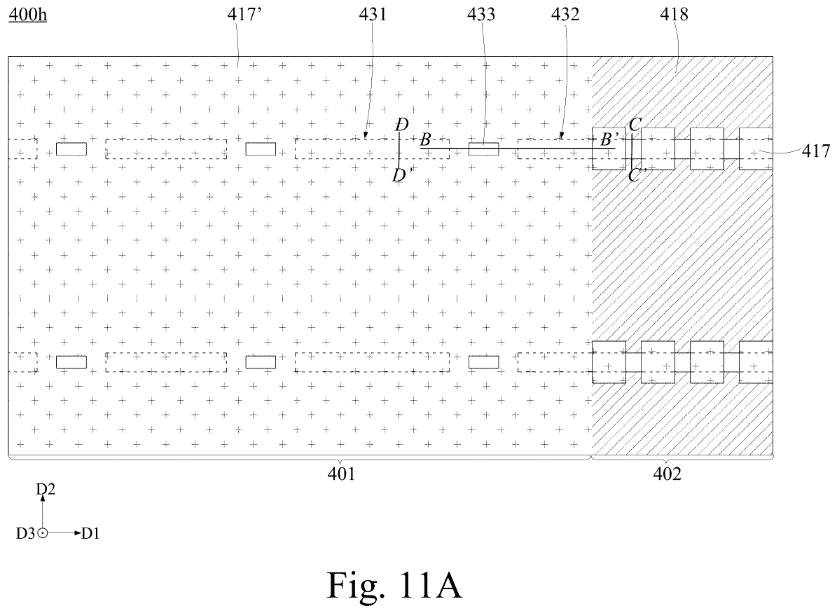

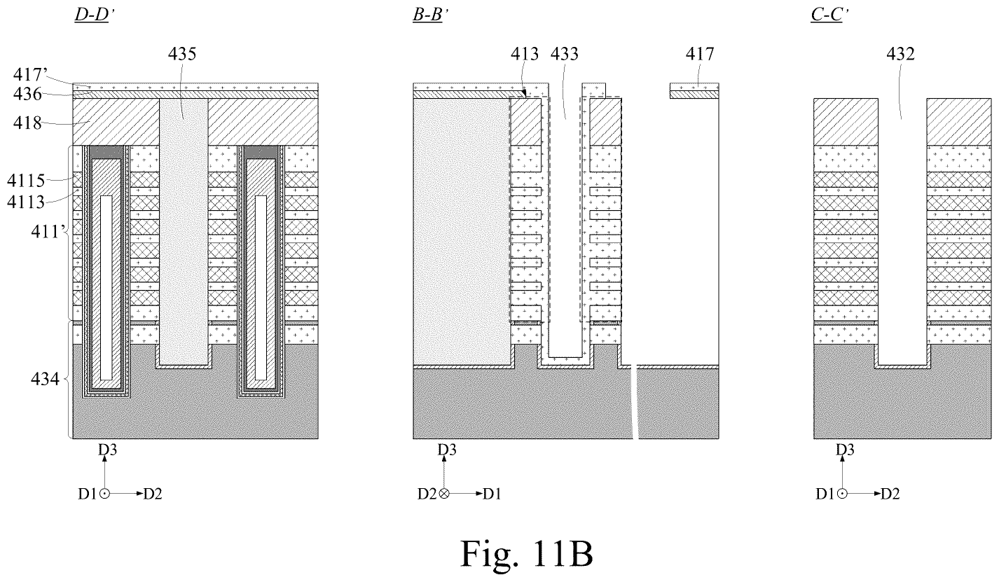

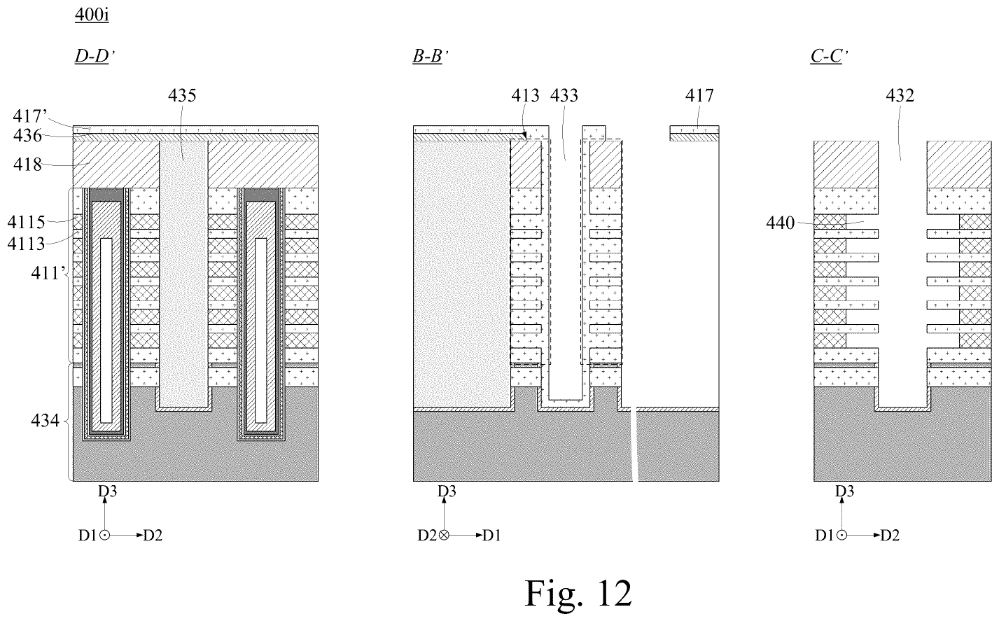

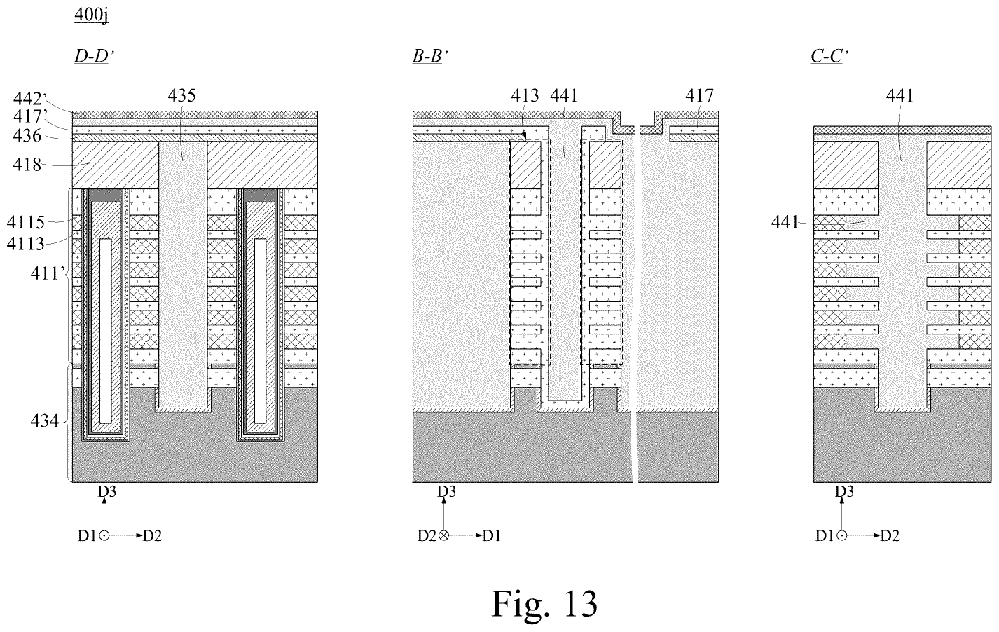

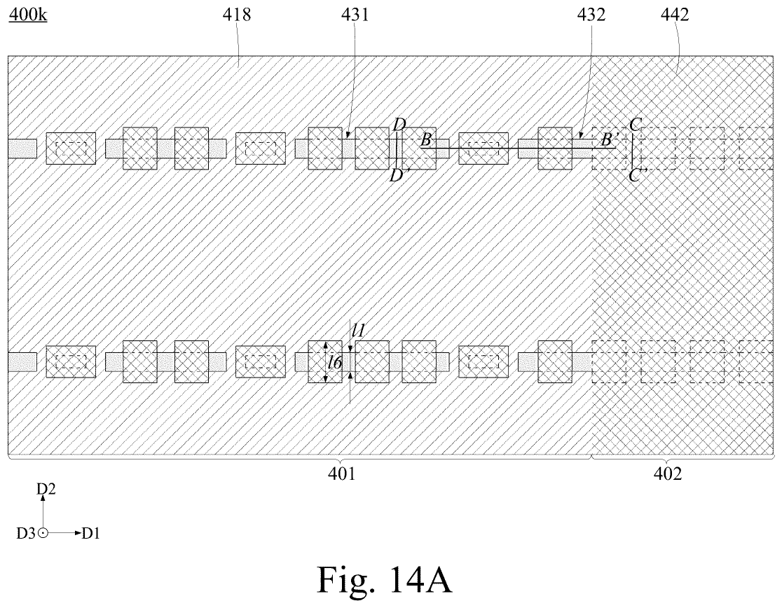

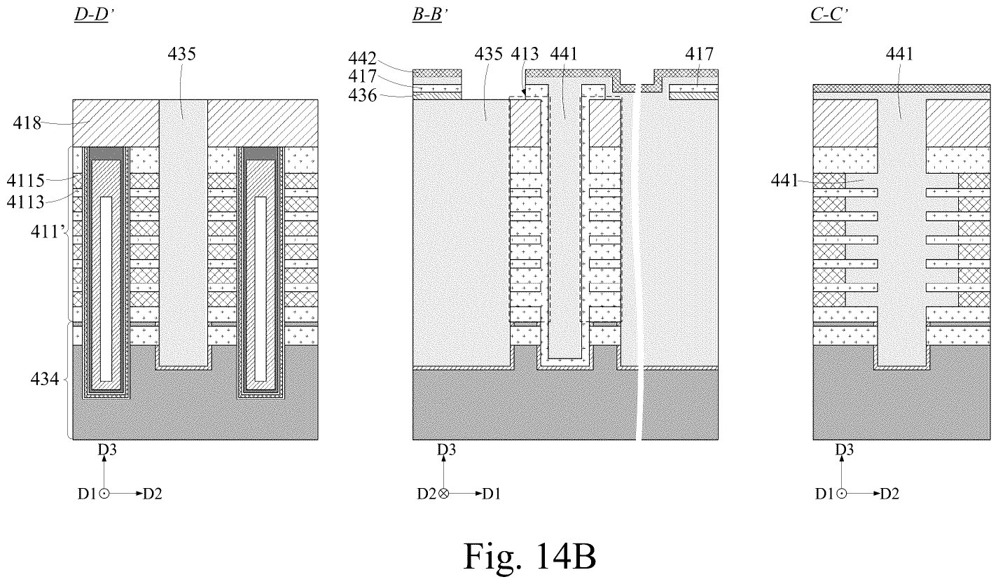

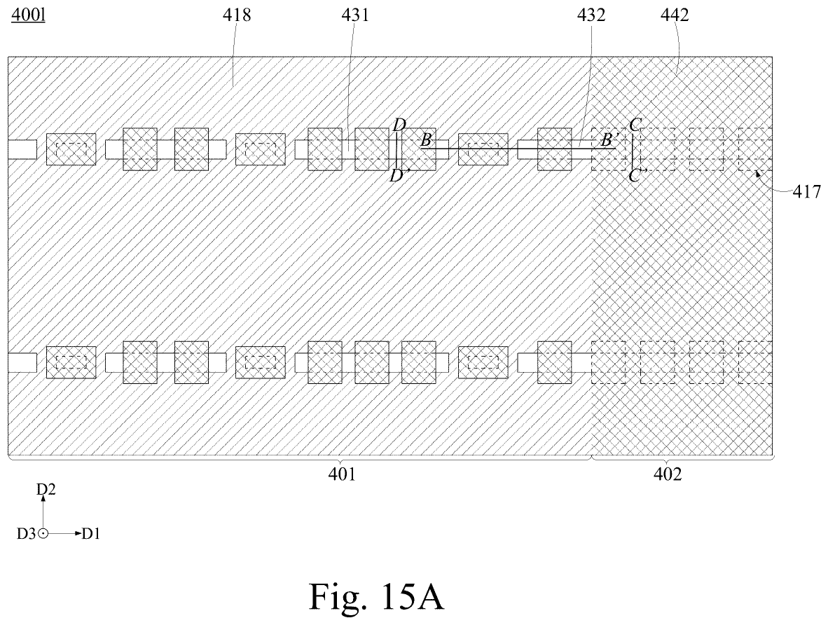

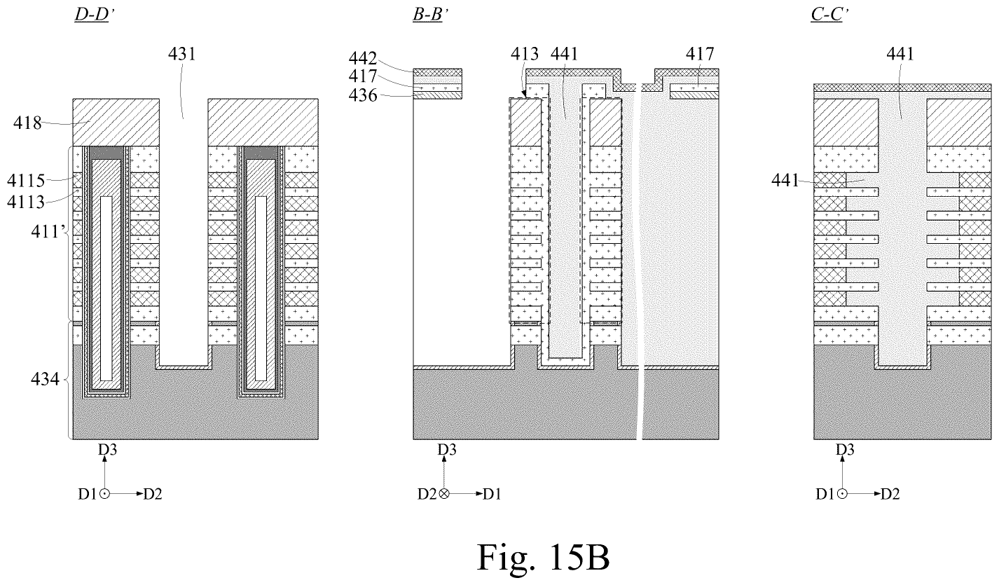

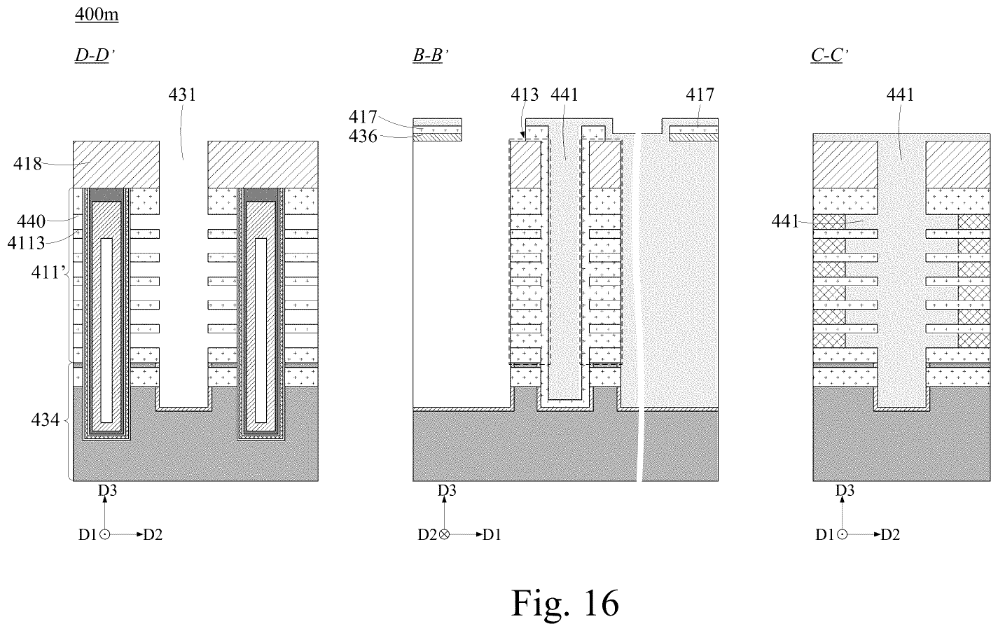

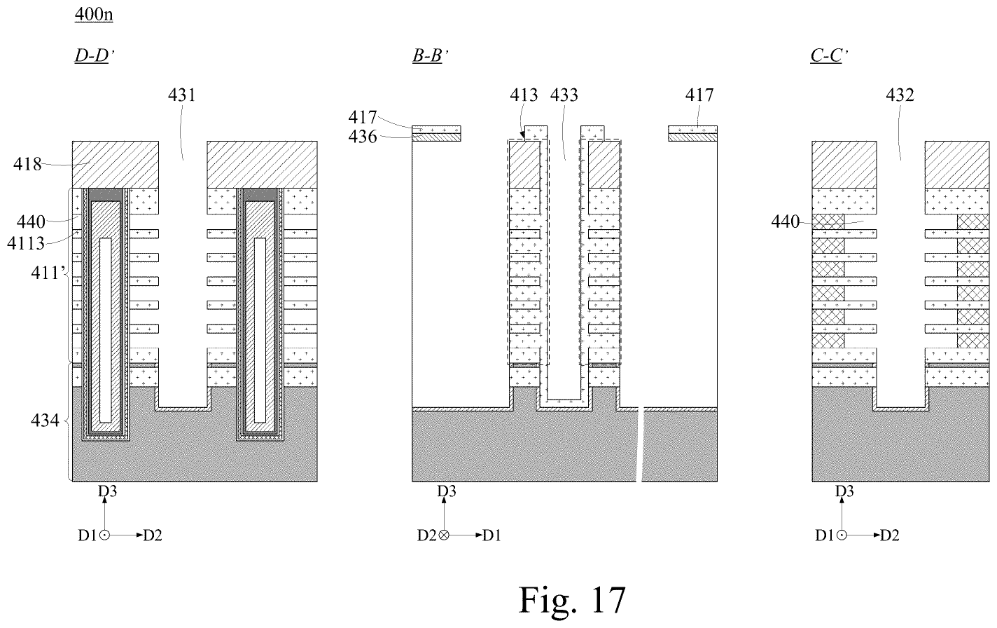

FIGS. 10A to 17 show the respective intermediate structures when performing the above operations. FIGS. 10A and 10B show the intermediate structure 400g after forming the plurality of fourth dielectric layers 417 in the connection region 402. FIGS. 11A and 11B show an intermediate structure 400h after removing the first sacrificial material layer 435 in the connection region 402. FIG. 12 shows an intermediate structure 400i after forming the second gaps 440 in the connection region 402. FIG. 13 shows an intermediate structure 400j after forming the second sacrificial material layer 441. FIGS. 14A and 14B show the intermediate structure 400k after forming the plurality of fourth dielectric layers 417 in the storage region 401. FIGS. 15A and 15B show an intermediate structure 400l after removing the first sacrificial material layer 435 in the storage region 401. FIG. 16 shows an intermediate structure 400m after forming the second gaps 440 in the storage region 401. FIG. 17 shows an intermediate structure 400n after removing the second sacrificial material layer 441.

In some implementations, as shown in FIGS. 9, 10A and 10B, it is possible to remove parts of the initial fourth dielectric layers 417′ in the connection region 402 with etching process such as dry etching process and leave the initial fourth dielectric layers 417′ in the storage region 401. The initial fourth dielectric layers 417′ not being removed in the connection region 402 may serve as the plurality of fourth dielectric layers 417 in the connection region 402. The plurality of fourth dielectric layers 417 in the connection region 402 may be discontinuously located on a side (e.g., surface) of the first sacrificial material layer 435 in the second slit part 432. For example, it is possible to make the size l6 of the left fourth dielectric layers 417 in the D2 direction greater than the size l2 of the first sacrificial material layer 435 in the D2 direction by patterning design. It is to be noted that FIGS. 10A and 10B show that only the second slit part 432 is located in the connection region 402. In other implementations, both the first slit part and the second slit part may be located in the connection region such that the plurality of fourth dielectric layers in the connection region may be discontinuously located on a side (e.g., surface) of the first sacrificial material layer in the first slit part and/or the second slit part.

In some implementations, as shown in FIGS. 10A to 11B, after forming the plurality of fourth dielectric layers 417 in the connection region 402, the first sacrificial material layer 435 in the second slit part 432 in the connection region 402 may be removed with etching process such as wet etching process such that the second slit part 432 in the connection region 402 is exposed. Since the plurality of fourth dielectric layers 417 in the connection region 402 are discontinuously arranged, in the process of removing the first sacrificial material layer 435 in the connection region 402, parts of the first sacrificial material layer 435 not being covered by the plurality of fourth dielectric layers 417 may contact with the etching material such as etchant and thus be removed, and the plurality of fourth dielectric layers 417 in the connection region 402 may be left.

In some implementations, as shown in FIGS. 11A, 11B and 12, after removing the first sacrificial material layer 435 in the second slit part 432 in the connection region 402, parts of the respective second dielectric layers 4115 located on two sides of the second slit part 432 may be removed with etching process such as wet etching process using the second slit part 432 in the connection region 402, thereby forming a plurality of second gaps 440 in the connection region 402.

In some implementations, as shown in FIGS. 12 and 13, a second sacrificial material layer 441 may be formed in the plurality of second gaps 440 in the connection region 402 and the second slit part 432 in the connection region 402 with thin film deposition process such as CVD, PVD, ALD or any combination thereof. The material for the second sacrificial material layer 441 may include poly-crystalline silicon (poly-Si), carbon (C) or any other suitable easy-to-remove materials. For example, the material for the second sacrificial material layer 441 may be spin-on carbon (SOC). For example, in the process of forming the second sacrificial material layer 441, the second sacrificial material layer 441 may be formed in the first trench 433. As another example, in the process of forming the second sacrificial material layer 441, a film layer of the same material as the second sacrificial material layer 441 may be formed on a side of the initial stack structure 411′ facing away from the substrate 434 in the D3 direction.

In some implementations, as shown in FIG. 13, after forming the second sacrificial material layer 441, an initial second mask layer 442′ may be formed on a side of the initial stack structure 411′ facing away from the substrate 434 in the D3 direction with thin film deposition process such as CVD, PVD, ALD or any combination thereof. The material for the initial second mask layer 442′ may be different from that of the first sacrificial material layer 435. For example, the material for the initial second mask layer 442′ may include silicon oxynitride (SiOₓN_{y}). The initial fourth dielectric layer 417′ in the storage region 401 may be located on a side of the initial second mask layer 442′ towards the substrate 434.

In some implementations, as shown in FIGS. 13, 14A and 14B, after forming the second sacrificial material layer 441, it is possible to remove the initial second mask layer 442′ in the storage region 401, the initial fourth dielectric layer 417′ in the storage region 401, the film layer of the same material as the second sacrificial material layer 441 between the initial second mask layer 442′ in the storage region 401 and the initial fourth dielectric layer 417′ in the storage region 401, and a part of the composite layer formed by the first mask layer 436 in the storage region 401 with etching process such as dry etching process, and leave the composite film layer in the connection region 402, and the initial fourth dielectric layers 417′ in the composite film layer not being removed in the storage region 401 may serve as the plurality of fourth dielectric layers 417 in the storage region 401. The plurality of fourth dielectric layers 417 in the storage region 401 may be discontinuously located on a side (e.g., surface) of the first sacrificial material layer 435 in the first slit part 431 and the second slit part 432. For example, it is possible to make the size l6 of the fourth dielectric layer 417 left in the storage region 401 in the D2 direction greater than the size l1 and l2 of the first sacrificial material layer 435 in the D2 direction by patterning the design. For example, the composite film layer not being removed in the storage region 401 may also be located on a side (such as surface) of the insulating structure 413 facing away from the substrate 434 in the D3 direction.

In some implementations, as shown in FIGS. 14A to 15B, after forming the plurality of fourth dielectric layers 417 in the storage region 401, the first sacrificial material layer 435 in the first slit part 431 and the second slit part 432 in the storage region 401 may be removed with etching process such as wet etching process such that the first slit part 431 and the second slit part 432 in the storage region 401 are exposed. Since the plurality of fourth dielectric layers 417 in the storage region 401 are arranged at intervals, in the process of removing the first sacrificial material layer 435 in the storage region 401, parts of the first sacrificial material layer 435 not being covered by the plurality of fourth dielectric layers 417 may contact with the etching material such as etchant and thus be removed, and the plurality of fourth dielectric layers 417 in the storage region 401 may be left.

In some implementations, as shown in FIGS. 15A, 15B and 16, after removing the first sacrificial material layer 435 in the first slit part 431 and the second slit part 432 in the storage region 401, the respective second dielectric layers 4115 in the storage region 401 may be removed with etching process such as wet etching process using the first slit part 431 and the second slit part 432 in the storage region 401, thereby forming a plurality of second gaps 440 in the storage region 401. Optionally, after forming the plurality of second gaps 440 in the storage region 401, the second mask layer 442 in the storage region 401 and the connection region 402 may be removed.

In some implementations, as shown in FIGS. 16 and 17, the second sacrificial material layer 441 in the second slit part 432 in the connection region 402 may be removed with etching process such as wet etching process. For example, in the above removing process, the second sacrificial material layer 441 in the first trench 433 may be removed. After the above-described processes, the respective second gaps in the storage region 401 and the connection region 402 communicate with each other, and the first slit part 431, the second slit part 432 and the first trench 433 are exposed. The plurality of fourth dielectric layers 417 cross the first slit part 431 and the second slit part 432 in the D2 direction, which can reinforce the initial stack structure 411′, and prevent the initial stack structure 411′ from falling down in the presence of a plurality of second gaps 440.

It is to be noted that although the above content has described an example of first forming a plurality of fourth dielectric layers 417 and a plurality of second gaps 440 in the connection region 402, and then forming a plurality of fourth dielectric layers 417 and a plurality of second gaps 440 in the storage region 401, in some other implementations, it is possible to first form a plurality of fourth dielectric layers and a plurality of second gaps in the storage region and then form a plurality of fourth dielectric layers and a plurality of second gaps in the connection region. In yet other some implementations, it is possible to form a plurality of fourth dielectric layers in the storage region and the connection region in the same etching process and form a plurality of second gaps in the same process. The above implementations are not specifically limited in the present application.

### Example Implementation(s) of Operation S330

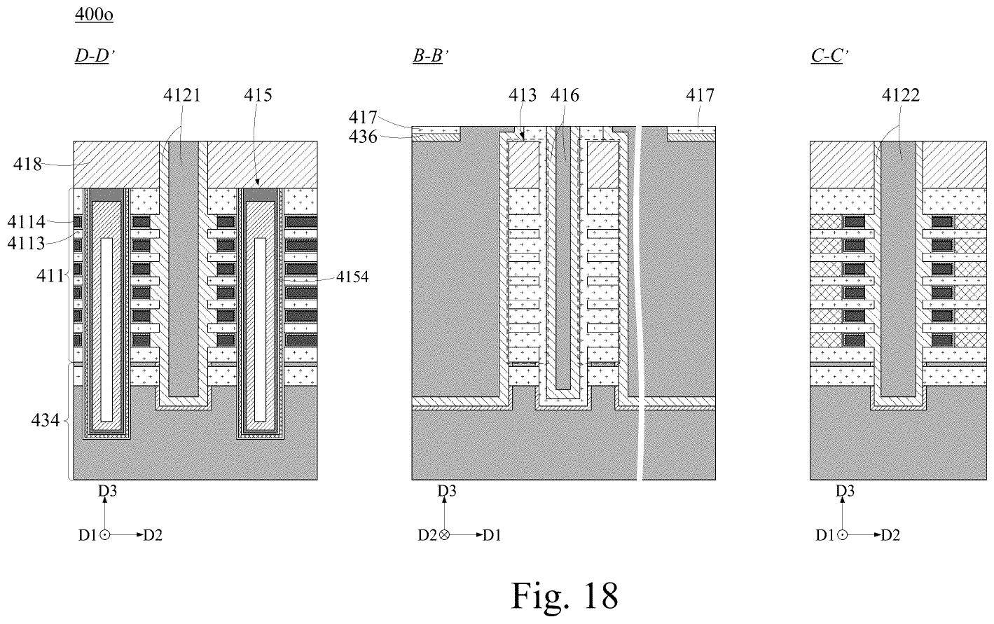

FIG. 18 shows an intermediate structure 4000 after forming the first isolation part 4121 and the second isolation part 4122.

As shown in FIGS. 17 and 18, it is possible to form the first isolation part 4121 and the second isolation part 4122 in the first slit part 431 and the second slit part 432 respectively with thin film deposition process such as CVD, PVD, ALD or any combination thereof. For example, it is possible to form silicon oxide (SiO₂) and poly-crystalline silicon (poly-Si) in turn in the first slit part 431 and the second slit part 432 respectively.

In some implementations, as shown in FIGS. 17 and 18, before forming the first isolation part 4121 and the second isolation part 4122, the method of fabrication 300 may further include an operation of forming a plurality of gate layers 4114 in the plurality of second gaps 440. Therefore, the initial stack structure 411′ is transformed into the stack structure 411.

In some implementations, as shown in FIGS. 17 and 18, the method of fabrication 300 may further include an operation of forming a filling structure 416 in the first trench 433. The filling structure 416 may be formed with thin film deposition process such as CVD, PVD, ALD or any combination thereof. For example, the following materials (or material combination) may be formed in the first trench 433: silicon oxide (SiO₂) and poly-crystalline silicon (poly-Si); silicon nitride (Si₄N4) and poly-crystalline silicon (poly-Si); silicon oxide (SiO₂); silicon oxide (SiO₂), poly-crystalline silicon (poly-Si) and silicon oxide (SiO₂), to form the filling structure 416.

In some implementations, the filling structure 416, the first isolation part 4121 and the second isolation part 4122 may be formed in the same thin film process. For example, it is possible to form silicon oxide (SiO₂) on inner walls of the first trench 433, the first slit part 431 and the second slit part 432 with the same thin film deposition process. Subsequently, it is possible to form poly-crystalline silicon (poly-Si) on the inner side of silicon oxide (SiO₂) in the first trench 433, the first slit part 431 and the second slit part 432 with thin film deposition process. In this implementation, the constituting materials for the filling structure 416, the first isolation part 4121 and the second isolation part 4122 may be the same.

In some implementations, the method of fabrication 300 may further include an operation of forming the semiconductor layer. For example, as shown in FIG. 18, it is possible to remove part of the substrate 434 and remove a part of the channel structure 415 that projects beyond the stack structure 411 to expose the channel layer 4154. Next, it is possible to form the semiconductor layer 214 connected (e.g., contacting) with the channel layer 4154 on a side of the stack structure 411 facing away from the insulating layer 418 with thin film deposition process such as CVD, PVD, ALD or any combination thereof (referring to FIG. 2C).

The method of fabrication of the semiconductor structure as provided according to the above-described examples facilitates improving the falling problem during the fabrication process and improving structure stability and yield.

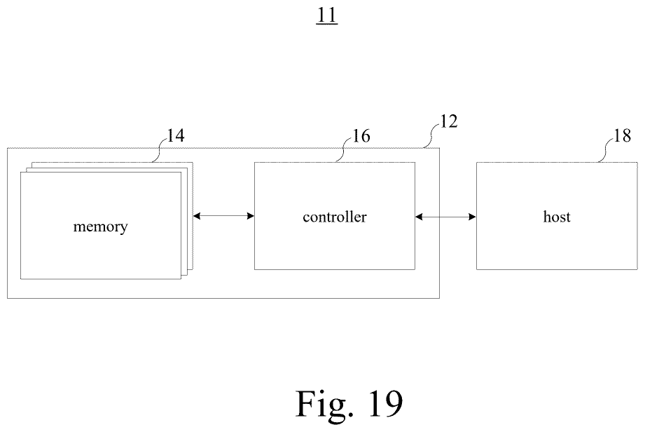

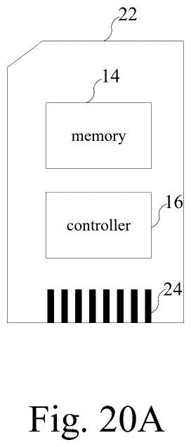

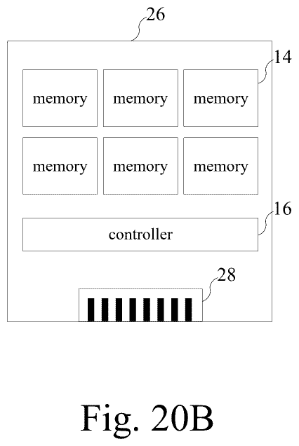

An example of the present application further provides a memory system. FIG. 19 is a block diagram of a system having a memory system in an example of the present application. FIGS. 20A and 20B are diagrams of a memory system in an example of the present application.

As shown in FIG. 19, the system 11 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having memory system 12 therein. As shown in FIG. 19, system 11 may include a host 18 and a memory system 12 having one or more memories 14 and a controller 16. The host 18 may be a processor of the electronic device such as a central processing unit (CPU) or a system-on-chip (SoC), for example an application processor (AP). The host 18 may be configured to transmit or receive data to or from the memory 14.

The memory 14 may include the semiconductor structure described in any implementations of the present application, for example, the semiconductor structure 100 shown in FIG. 1 and the semiconductor structure 200 shown in FIGS. 2A to 2C. According to some implementations, the controller 16 is coupled to the memory 14 and the host 18 and is configured to control the memory 14. The controller 16 can manage the data stored in the memory 14 and communicate with the host 18. In some implementations, the controller 16 is designed for operating in a low duty-cycle environment like secure digital (SD) cards, compact Flash (CF) cards, universal serial bus (USB), Flash drives, or other media for use in electronic devices, such as personal computers, digital cameras, mobile phones, etc. In some implementations, the controller 16 is designed for operating in a high duty-cycle environment such as SSDs or embedded multi-media-cards (eMMCs) used as data storage for mobile devices, such as smartphones, tablets, laptop computers, etc., and enterprise storage arrays. The controller 16 can be configured to control operations of the memory 14, such as read, erase, and program operations. The controller 16 can also be configured to manage various functions with respect to the data stored or to be stored in the memory 14 including, but not limited to bad-block management, garbage collection, logical-to-physical address conversion, wear leveling, etc. In some implementations, the controller 16 is further configured to process error correction codes (ECCs) with respect to the data read from or written to the memory 14. Any other suitable functions may be performed by the controller 16 as well, for example, formatting the memory 14. The controller 16 can communicate with an external device (e.g., the host 18) according to a particular communication protocol. For example, the controller 16 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

The controller 16 and one or more memories 14 can be integrated into various types of memory systems, for example, be included in the same package, such as a universal Flash storage (UFS) package or an eMMC package. That is, the memory system 12 can be implemented and packaged into different types of end electronic products. In one example as shown in FIG. 20A, the controller 16 and a single memory 14 can be integrated into a memory card 22. The memory card 22 may include a PC card (PCMCIA, Personal Computer Memory Card International Association), a CF card, a smart media (SM) card, a memory stick, a multimedia card (MMC, RS-MMC, MMCmicro), a SD card (SD, miniSD, microSD, SDHC), a UFS etc. The memory card 22 can further include a memory card connector 24 coupling the memory card 22 with a host (e.g., the host 18 in FIG. 19). In another example as shown in FIG. 20B, the controller 16 and multiple memories 14 can be integrated into an SSD 26. SSD 26 can further include an SSD connector 28 coupling SSD 26 with a host (e.g., the host 18 in FIG. 19). In some implementations, the storage capacity and/or the operation speed of the SSD 26 is greater than those of the memory card 22.

The description above is only for the purpose of explaining implementations of the present application and the technical principles they used. It will be appreciated by those skilled in the art that the protection scope claimed by the present application is not limited to technical solutions composed of particular combinations of the above-mentioned technical features, and instead will cover, without departing from the present technical concept, any other technical solutions composed of any combinations of the above-mentioned features and their equivalents, for example, the technical solutions resulted from substitutions of the above-mentioned features by technical features having similar functions disclosed in the present application (but not limited to this).

What is claimed is:

1. A semiconductor structure, comprising:
a stack structure;
a gate line isolation structure penetrating through the stack structure and comprising a first isolation part and a second isolation part arranged in a first direction and both extending in the first direction; and
an insulating structure penetrating through the stack structure and connected between the first isolation part and the second isolation part;
wherein the first direction intersects a stacking direction of the stack structure.

2. The semiconductor structure of claim 1, wherein in a second direction, a size of the insulating structure is greater than a size of the first isolation part and greater than a size of the second isolation part, and the first direction, the second direction and the stacking direction intersect each other.

3. The semiconductor structure of claim 1, further comprising:
a filling structure penetrating through the insulating structure and having separating distances from the first isolation part and the second isolation part respectively in the first direction.

4. The semiconductor structure of claim 3, wherein materials for the filling structure comprise, from outside to inside, one of: silicon oxide and poly-crystalline silicon; silicon oxide, silicon nitride and poly-crystalline silicon; silicon oxide; or silicon oxide, poly-crystalline silicon and silicon oxide.

5. The semiconductor structure of claim 4, wherein materials for the first isolation part, the second isolation part and the filling structure are the same.

6. The semiconductor structure of claim 1, wherein a material for the insulating structure comprises silicon oxide.

7. The semiconductor structure of claim 1, wherein in a plane perpendicular to the stacking direction, the stack structure is divided into a storage region and a connection region in the first direction, and a plurality of the insulating structures are arranged at intervals in the first direction in the storage region.

8. The semiconductor structure of claim 7, wherein in the first direction, a size between adjacent insulating structures is greater than or equal to 5 μm, and a size of the insulating structure is greater than or equal to 500 nm.

9. The semiconductor structure of claim 1, further comprising:
a plurality of dielectric layers discontinuously covering end surfaces of the first isolation part and the second isolation part in the stacking direction,
wherein in a second direction, a size of the dielectric layer is greater than a size of the first isolation part and greater than a size of the second isolation part, and the first direction, the second direction and the stacking direction intersect each other.

10. The semiconductor structure of claim 9, wherein in the first direction, a size between adjacent dielectric layers is greater than or equal to 300 nm, and a size of the dielectric layer is greater than or equal to 150 nm.

11. The semiconductor structure of claim 9, wherein a material for the plurality of dielectric layers comprises silicon oxide.

12. The semiconductor structure of claim 9, wherein the stack structure is divided into memory blocks by the gate line isolation structures and the insulating structures adjacent in the second direction, and the dielectric layers connect adjacent memory blocks.

13. The semiconductor structure of claim 1, wherein sidewalls of the first isolation part and the second isolation part are all in plane shapes.

14. The semiconductor structure of claim 2, further comprising:
a channel structure extending in the stacking direction in the insulating structures.

15. A memory system, comprising:
a memory comprising a semiconductor structure, the semiconductor structure comprising:
a stack structure;
a gate line isolation structure penetrating through the stack structure and comprising a first isolation part and a second isolation part arranged in a first direction and both extending in the first direction; and
an insulating structure penetrating through the stack structure and connected between the first isolation part and the second isolation part;
wherein the first direction intersects a stacking direction of the stack structure; and
a controller coupled with the memory and configured to control the memory to store data.

16. A method of fabricating a semiconductor structure, comprising:
forming a first slit part, a first trench and a second slit part penetrating through an initial stack structure, wherein the initial stack structure includes first dielectric layers and second dielectric layers stacked alternatively, the first slit part, the first trench and the second slit part are arranged at intervals in a first direction, and the first slit part and the second slit part both extend in the first direction; and
replacing parts of the respective second dielectric layers at a periphery of the first trench with a plurality of third dielectric layers; and
forming a first isolation part and a second isolation part in the first slit part and the second slit part respectively,
wherein the first direction intersects a stacking direction of the initial stack structure.

17. The method of claim 16, wherein before replacing parts of the respective second dielectric layers at the periphery of the first trench with the plurality of third dielectric layers, the method further comprises:
forming a sacrificial material layer in the first slit part and the second slit part;
wherein replacing parts of the respective second dielectric layers at the periphery of the first trench with the plurality of third dielectric layers comprises:
removing parts of the respective second dielectric layers at the periphery of the first trench to the sacrificial material layer and forming a plurality of first gaps; and
forming the plurality of third dielectric layers in the plurality of first gaps.

18. The method of claim 17, wherein after replacing parts of the respective second dielectric layers at the periphery of the first trench with the plurality of third dielectric layers, the method further comprises:
forming an initial fourth dielectric layer on sides of the initial stack structure and the sacrificial material layer in the stacking direction; and
removing a part of the initial fourth dielectric layer such that a plurality of fourth dielectric layers left are discontinuously located on a side of the sacrificial material layer, and the respective fourth dielectric layers left have sizes in the second direction being greater than a size of the sacrificial material layer in the second direction;
wherein the first direction, the second direction, and the stacking direction intersect each other.

19. The method of claim 18, wherein before forming the first isolation part and the second isolation part in the first slit part and the second slit part respectively, the method further comprises:
removing the sacrificial material layer and exposing the first slit part and the second slit part;
removing at least parts of the respective second dielectric layers with the first slit part and the second slit part to form a plurality of second gaps; and
forming a plurality of gate layers in the plurality of second gaps.

20. The method of claim 19, wherein in a plane perpendicular to the stacking direction, the initial stack structure is divided into a storage region and a connection region in the first direction, the first slit part is located in the storage region, and the second slit part is located in the storage region and the connection region;
wherein removing at least parts of the respective second dielectric layers with the first slit part and the second slit part to form the plurality of second gaps comprises:
removing parts of the respective second dielectric layers in the connection region with the second slit part; and
removing the respective second dielectric layers in the storage region with the first slit part and the second slit part to form the plurality of second gaps.
